(19) United States
(12) Patent Application Publication
(10) Pub. No.: US 2008/0023060 A1
(43) Pub. Date: Jan. 31, 2008

(54) Apparatus for Distributing Light Energy Particularly for Photovoltaic Conversion

(76) Inventor: Mihai Grumazescu, Manitoba (CA)

Correspondence Address: ADE & COMPANY INC., 2157 Henderson Highway, WINNIPEG, MB, R2G1P9, US

(21) Appl. No.: 11/570,693

(22) PCT Filed: Jun. 6, 2005
(86) PCT No.: PCT/CA05/00944

§ 371 Date: Dec. 15, 2006

Related U.S. Application Data
(60) Provisional application No. 60/580,354, filed on Jun. 18, 2004.

(51) Int. Cl. H01L 31/052; H01L 31/0232

(52) U.S. Cl. 136/246

(57) ABSTRACT

A light distribution system is used in a method for converting solar or artificial light into electricity by collecting, concentrating and time-sharing light to a number of photovoltaic cells. A convergent lens and an optional optical collimator provide an intense parallel beam directed onto a spinning mirror reflecting the beam in a radial plane to its axis of rotation and time-distributing it to a number of photovoltaic cells which are in an inside surface of a cylinder in the plane. The apparatus has DC or AC output capability, in accordance with the connecting pattern of the PV cells and is protected against burnout due to spinning mirror failure by stopping the beam at a window. A light pipe can be used to carry the light from the collector to the mirror. The device can be used to transmit power in a laser beam to a remote station such as a robot. The same concept of distributing collimated natural or artificial light can be used where the receivers are optical fibers instead of PV cells to supply a series of lighting fixtures fed by the same collector

This invention relates to an apparatus for distributing light energy particularly for photovoltaic conversion of the energy of the sunlight or originating from an artificial source of light into electricity. More particularly, this invention concerns photovoltaic conversion using concentrated light. However the apparatus can be used for distributing light for light fixtures of other purposes.

### BACKGROUND OF THE INVENTION

In most cases, solar energy is turned into electricity by deploying photovoltaic (PV) modules tracking or not tracking the sun. The more collecting surface built, the more electric power obtained. Solar modules have up to 25 years warranty and PV systems may be designed to be maintenance-free for several years. Sunlight is free and PV conversion is a mature technology and a marvellous zero-emission source of energy. Despite all these, in the last years, a new concern discouraged investors, final users and even governments to support PV conversion: global warming.

Apparently, more sunny days should favor the PV option but unexpected extreme weather conditions—high winds, dust storms and hail—are worrying the potential users thinking of the great possible damage. Not to mention the fact that the PV modules are the most expensive link of a whole PV system! Some manufacturers are even advertising and including in the data sheets the maximum dimension of hailstones to which PV modules are immune and the maximum wind load of the array.

Than why not try to minimize the outdoor segment of the PV system which has to be some kind of solar collector and to hide the PV cells in a protected enclosure? Because every solution has a price, we have to forget about the main advantage of a classic solar module: no moving parts.

In the PV conversion field, best efficiencies are known as being achieved using concentrated light. The prior art is abundant in fixed assemblies of collectors, concentrators and PV cells displaying a variety of solutions for each of them. The problems concerning heat transfer from the semiconductor junctions to heat-sinks are also already solved using even miniature heat pipes. The only drawback of the prior art is that scaling up this technology implies enlarging the collector's surface. The present invention is proposing to change the scaling criteria and to keep the collector's surface as small as possible resulting in a very high collecting surface/output electric power ratio.

It is an object of the present invention to provide a method and an apparatus for PV generation in order to reduce and protect the collecting surface against weather conditions and to move the PV generation indoor, increasing its efficiency in the same time. An additional feature of this concept is the possibility of generating DC or AC, according to the connection pattern of the PV cells, cutting costs by the elimination of the inverters when AC loads are a must. Another advantage of the concept is the reduction of the cleaning needed for maintaining the collector's surface.

Military—especially ground forces and the navy—could be interested by this concept due to the very low profile of the outdoor system's segment which makes it a very robust and hard to be observed/destroyed piece of equipment.

It is another object of the present invention to provide a method and apparatus for PV generation using as input energy an artificial source of light, preferably an IR laser. This can be useful for transmitting power to distant telecommunication relays, remote sensing devices, robots, etc.

Another object of the invention aims the enhancement of actual hybrid or artificial-remote lighting systems. The advantage of saving energy by distributing light from a common source to hundreds of light fixtures is capable of booming the deployment of such systems. Lighting and power generation can be associated for making them even more affordable in this early stage of the technology.

### SUMMARY OF THE INVENTION

According to the invention there is provided an apparatus comprising:
a collector for light from a source;
a plurality of light receivers each for receiving light from the collector;
the light receivers being arranged in an array surrounding an axis;
the collector being arranged to direct the light in a beam along the axis;
a light redirecting member arranged on the axis and arranged to redirect the light in the beam away from the axis such that the redirected beam lies in a plane radial to the axis;
and a drive arrangement for rotating the light redirecting member around the axis such that the redirected beam rotates around the axis and falls sequentially and repeatedly on each of the receivers as the member rotates.

In one preferred operation, the receivers are arranged for converting light into electricity and each comprises a respective one of a plurality of PV cells. However the same system can be used for distributing light in many different end uses where the receivers can be light pipes or other elements.

In one preferred operation, the collector is arranged for collecting sunlight. However the collector can be arranged for receiving light energy from any source where useably energy is available.

Thus for example, the collector can be arranged for collecting light from an electric light source.

Preferably the light redirecting member comprises a mirror so that the light is redirected by a spinning mirror. However other devices for redirecting light as will be well known to one skilled in the art can be used.

Preferably the light redirecting member is driven by an electric motor. However other motive force can be used.

Preferably the collector includes a collimator for guiding the beam parallel to the axis.

Preferably the light redirecting member is arranged to direct the light into a radial plane of the axis. In this case the receivers lie on the inside surface of a cylinder. However this is not essential and different angles to the axis may be used but in that case the receivers may lie in a cone, that is, on an inside of a surface surrounding the axis.

Preferably there is provided a magnetic brake for always stopping the light redirecting member in the same rest angular position.

Preferably there is provided a drive member for driving the magnetic brake axially for engaging a cooperating element on the light redirecting member.

Preferably there is provided a safety window corresponding to the rest angular position of the light redirecting member so that the light can be redirected away from the receivers to avoid damage. However other techniques for redirecting the light in the event of a failure can be used.

Preferably there is provided a vacuum enclosure housing surrounding the light redirecting member and the receivers.

Preferably there is provided a dual-axis tracking platform supporting the collector so as to track the light source.

Preferably there is provided a plurality of collectors arranged in an array.

Preferably the collectors are hexagonal and mounted in a honeycomb pattern.

Preferably the collectors are mounted in the same plane and there is provided for each collector an array of light receivers where the arrays are arranged in different planes in such a way that incident and reflected collimated beams are intersecting at right angles but are not shading or interfering to each other.

Preferably the collector is protected by a transparent, anti-reflecting dome against extreme weather conditions.

In some cases, the collector includes an optical cable or light pipe such that the concentrated light is transported through the optical cable to the light redirecting member.

In one arrangement, the light receivers are PV cells which are connected in series or in parallel for delivering DC.

In one arrangement, the light redirecting member light receivers are PV cells which are connected in phased clusters connected to a transformer for delivering a true-sine single or three-phase AC.

Preferably voltage, phase and frequency are controlled by controlling the rate of the rotation of the light redirecting member.

In one arrangement for generating of electric power, the source comprises a laser transmitted from a central station and the collector is mounted at a slave station so that the system provides a remote powering of the slave station, which may be movable as a robot.

Preferably each of the receivers comprises a respective one of a plurality of light transfer pipes such that, for example, concentrated and filtered sunlight can be piped from a roof sun-tracking collector through an optical cable and can be distributed by the light transfer pipes to a respective one of a plurality of lighting fixtures in a building.

### BRIEF DESCRIPTION OF THE DRAWINGS

One embodiment of the invention will now be described in conjunction with the accompanying drawings in which:

FIG. 1 is a 2-D longitudinal section of a first preferred embodiment;

FIG. 2 is a 3-D partial longitudinal section of the first preferred embodiment of FIG. 1;

FIG. 3 shows three versions of optical path and distribution of light inside the apparatus;

FIG. 4 is an isometric view of a second preferred embodiment defined by a single modular apparatus on a tracking platform;

FIG. 5 is an isometric view of a third preferred embodiment defined by a multiple modular apparatus on the same tracking platform;

FIG. 6 is a 3-D partial longitudinal section of the third preferred embodiment;

FIG. 7 is a schematic diagram of a device for burnout protection for use in the embodiments shown above;

FIG. 8 is a schematic diagram of a device for safety sensor fixture for use in the embodiments shown above;

FIGS. 9A, 9B and 9C are schematic diagrams of the connection patterns of the PV cells for AC and DC generation;

FIG. 10 is a schematic illustration of a preferred embodiment which uses laser transmission and distant PV generation.

In the drawings like characters of reference indicate corresponding parts in the different figures.

### DETAILED DESCRIPTION

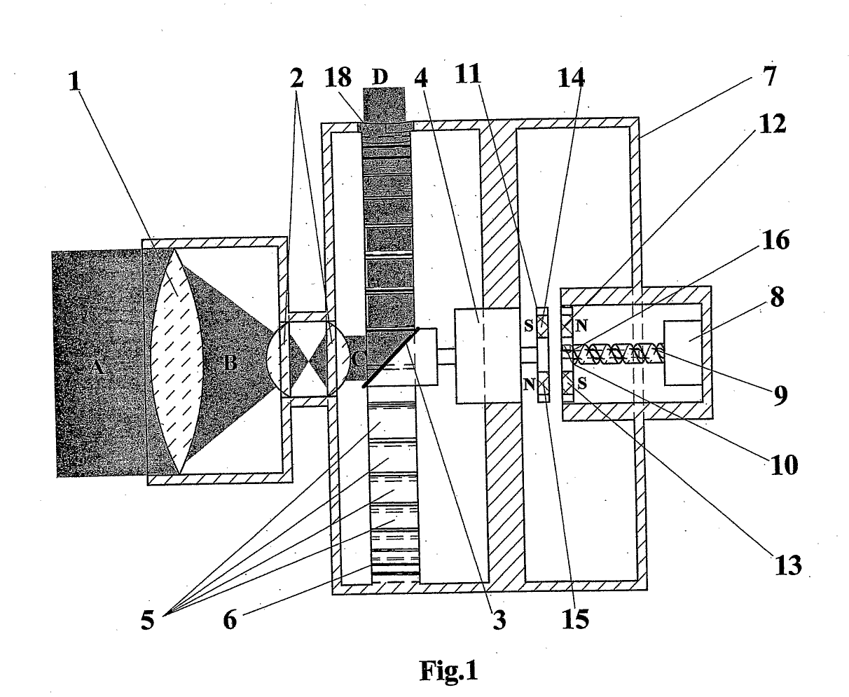

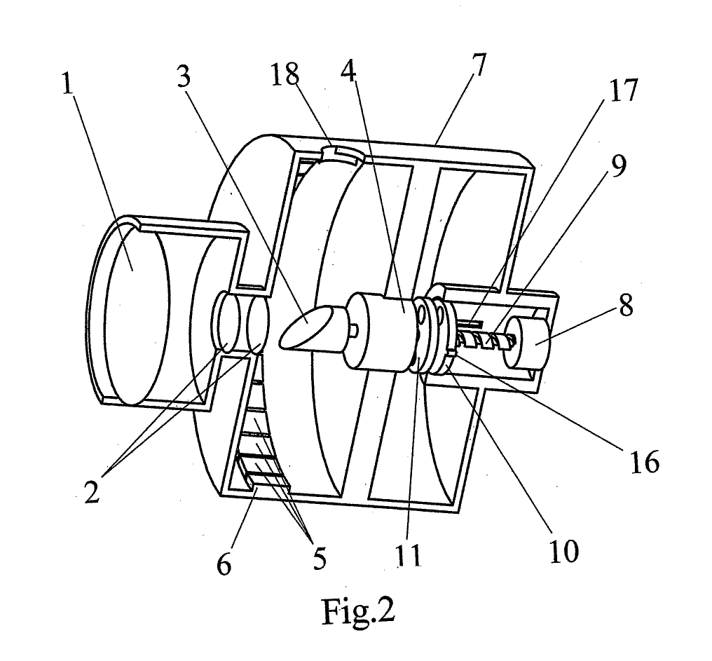

The preferred embodiment of the present invention is illustrated in FIG. 1 and FIG. 2. A lens 1 is concentrating the incoming light A in a convergent beam B which is further transformed by an optical collimator 2 in a parallel-ray beam C striking sequentially a number of PV cells 5 with its footprint of intense light D after being reflected by a fast spinning mirror 3.

The lens 1 is either a classic bi-convex one or a cheaper planar Fresnel lens, while the optical collimator comprises two identical plan-convex lenses. The spinning mirror 3 is made of a cylinder cut by a 45 degrees angled plane in respect to its axis of revolution and is driven by the high-speed electric motor 4. By spinning with over 10,000 rpm, mirror 3 is distributing in time-sharing the intense beam of light C to a large number of PV cells 5 embedded in an annular support 6 surrounding the axis of the mirror. The annular support 6 is mounted in an enclosure 7 and for an optimum operation, the enclosure 7 has to be under vacuum in order to be dust-free and to completely eliminate the drag induced by the air friction to the spinning mirror 3.

In this way, the motor 4 is operating with no back-torque and has a very low power consumption. Cheaper brush motors can also be used because sparks are rare in vacuum at low voltage and the motor's life is longer than in air operation. However, very low power brushless electric motors are preferred.

As the light intensity at the footprint D is arranged by the lens system to be magnified by a factor which can be over 400 times and consequently very hot, the main concern for safety is regarding a possible burnout of the PV cells if the mirror 3 is not spinning. If the motor 4 fails to start or stops during operation due to the driver circuit or its own failure, then one very effective and simple way to avoid burnout is to be sure that footprint D is always resting in the same point angularly around the axis at which is located a safety window 18. One simple way to implement a positional memory to the mirror in order to insure that is to add to its driving motor 4 a magnetic brake. Thus an electric motor 8 having a threaded shaft 9 drives linearly a nut-disc 10 back and forth in a longitudinal direction of the axis of the motor 4 in front of an axially aligned disc 11 fastened on the shaft of the motor 4. Both discs 10 and 11 carry two small cylindrical magnets each, 12, 13 and 14, 15 respectively. The magnets are magnetized in the direction of their thickness with the polarization shown in FIG. 1. The disc 10 is guided in longitudinal movement and prevented from rotation by two protrusions 16 sliding in cutouts 17 of the housing 7.

Each time the apparatus is turned off or during its operation one of the above mentioned failures takes place, a logic circuit takes the decision of cutting off power to the motor 4 and to starting the motor 8 for bringing the disc 10 close to the disc 11. The magnetic forces act to stop the shaft of the motor 4 precisely in the aligned position of the attracting magnets. In this way, the footprint D will rest exactly in its reset position corresponding to the safety window 18. Preferably, the motor 8 has a built-in transducer coupled to a simple counter for insuring a number of revolutions related to the pitch of its threaded shaft. So, the movement of the disc 10 will never exceed two preset positions. This magnetic brake has the advantage of being contact-less, accurate and reliable but other actuators, brakes or clutches can be envisaged by those skilled in the art, including electromagnetic, pneumatic and hydraulic.

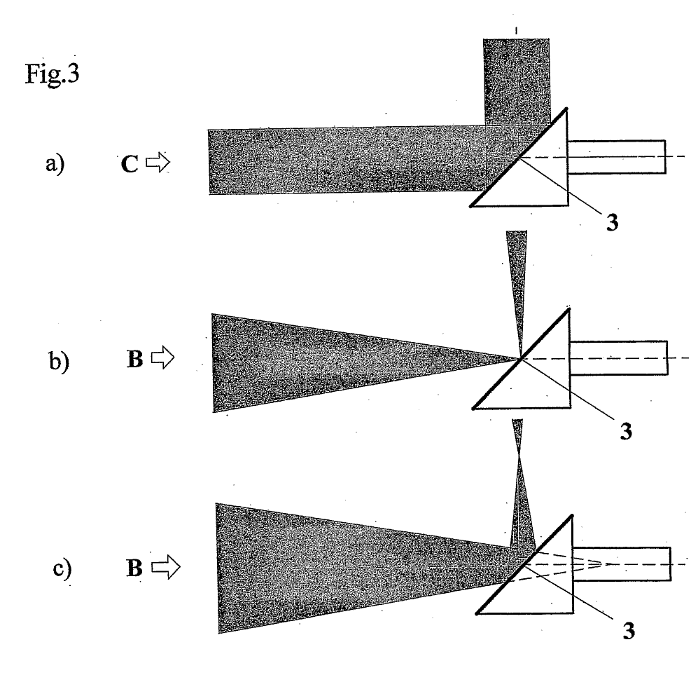

In FIGS. 3A, 3B and 3C there are illustrated three alternative versions of the optical path inside the apparatus.

FIG. 3A corresponds to the situation of using the optical collimator presented in FIG. 1 and FIG. 2, so the input beam for the mirror 3 as indicated at C is characterized by a constant cross section. This cross section will be reproduced in the footprint D, regardless of the radius of the support 6 i.e. the distance to the PV cells. This means that the number of PV cells can be changed as long as it is dictated only by the radius of the support 6. Furthermore, it means that the output electric power given by the number of PV cells is a function of the radius of the support 6 starting from the same optical arrangement, collecting surface and light intensification factor.

If the designer wishes to simplify the optics involved in the apparatus, then the optical collimator can be omitted, letting the convergent beam B strike directly the mirror 3. FIG. 3B presents the case in which the position of focus of the lens 1 falls on the mirror 3 and FIG. 3C envisages the possibility of advancing the position of the focus behind the mirror. In both cases, the radius of the support 6 has to be calculated in order to match the footprint D with the active area of the PV cells. Setting the focus of the lens 1 directly on the mirror 3 is less practical. It is necessary to avoid the overheating of the mirror 3, which is the most critical part of the apparatus, because it has to comply with several initial mechanical, optical and thermal conditions linked to each other and evolving during operation. Placing the focus of the beam on the mirror thus can lead to heating in a localized position with the potential of damage.

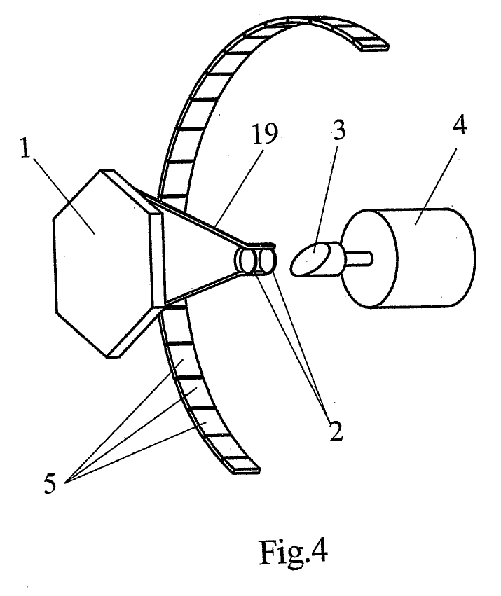

In FIG. 4 there is shown schematically a second preferred embodiment of the apparatus in which the Fresnel lens 1 is embedded in a hexagonal frame attached to a tapered enclosure 19 which houses also the optical collimator 2. This assembly thus forms a structural module representing part of or the entire outdoor exterior segment of the apparatus. The spinning mirror 3, the motor 4 and the PV cells 5 are the indoor or interior segment which can also be modular. These elements can thus be constructed and mounted separately. An important feature of this embodiment is the fact that the distance between the two segments is variable but their accurate axial alignment is a must.

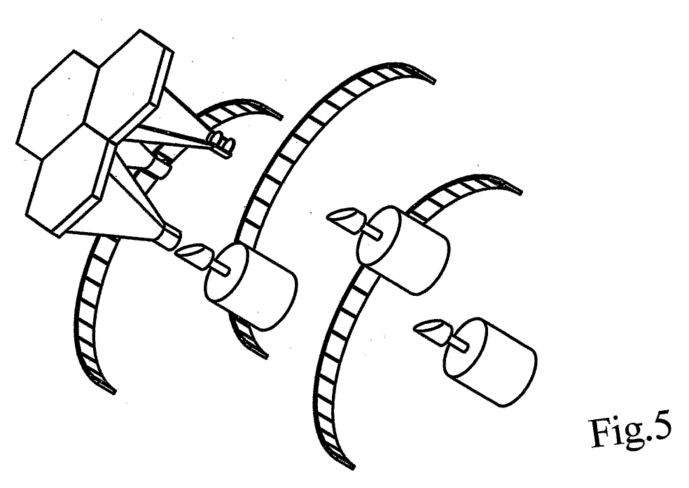

This feature is further used in FIG. 5 where a multiple PV generator is presented. The collector is a larger frame including several co-planar lenses each formed by a separate one of the exterior modules fastened in a honeycomb pattern while the interior modules are located in different parallel planes and preserving the axial optical alignment. This way, the beams of light of the different PV generators can intersect each other at right angle but are never interfering or shading each other.

A dual-axis tracking platform to support the single or multiple generators can be provided but, for convenience of illustration, is not shown in FIG. 4 and FIG. 5.

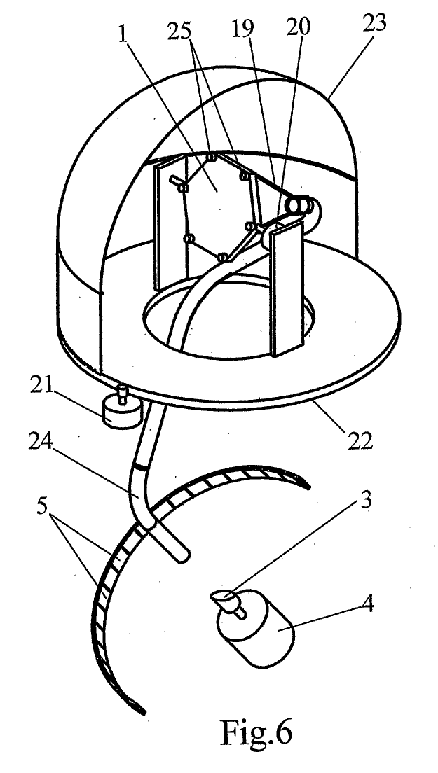

A third preferred embodiment of the present invention is illustrated in FIG. 6. The distance between the exterior and the interior modules is significantly increased by linking them through a flexible optical cable 24 which also enables the mounting of the interior module in a fixed position independent of the movement of the exterior module. The tracking platform includes a tilt motor 20 and an azimuth motor 21 together with a platform 22 supporting the lens 1 and the housing 19 which can also include optionally the optical collimator. The whole tracking platform is protected by a dome 23 made of a transparent, shock-resistant material coated with an anti-reflection layer. Light collected by the lens 1 is concentrated on the head of the flexible optical cable 24 and transported to the interior module where the spinning mirror 3 distributes the light to the PV cells 5. This is the best solution for a safe operation of the apparatus throughout the year in the most adverse environments. If the dome enclosure is under vacuum, the optics and the tracking mechanism will be even more protected against the outdoor temperature.

The dome shape is arranged to avoid retaining snow and water droplets, which is another advantage in order to reduce cleaning operations.

If desired, the dome can be cleaned remotely performed by an automated arm-tool carrying high-pressure water and washing agents. Even if the dome is scratched or cracked and has to be replaced, its price is considerably smaller than that of a PV module. But the most important is the fact that its low profile decreases tremendously the probability of being hit by a projectile of any kind, compared with a solar panel exposing a huge area to this threat. That is particularly advantageous for military and space applications.

The necessity for moving parts in the arrangement described above can be overcome by the many high quality and reliable components available on the market, and well known to one skilled in the art.

A further advantage of the concept illustrated by FIG. 6 is the flexibility of bringing the PV generator as close as possible to the load. This feature is highly appreciated by designers because the voltage drop is proportional to total wire length, this way cutting costs, increasing safety and diminishing power loss.

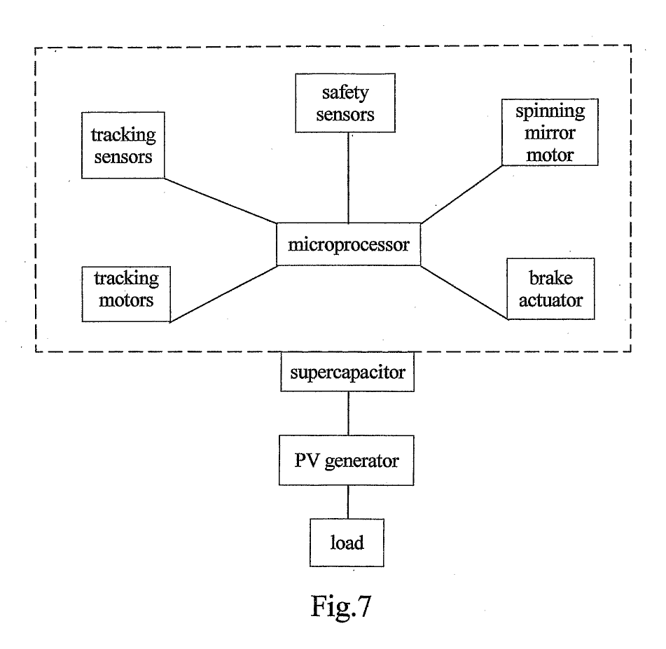

In FIG. 7 is shown the sequence of steps and presents the logic blocks and the structural elements involved in preventing the burnout of the apparatus. All decisions are taken by a microprocessor controlling the start-up, turn-off and alarms sequences as well as performing sun tracking, PV generation and load monitoring.

The start-up sequence begins with retracting the brake disc 10, starting the spinning mirror motor and continues with interrogation of tracking and safety sensors. If everything is OK, tracking motors are receiving the proper commands and after targeting the sun, PV generation begins.

At start-up or during operation, if safety sensors detect the spinning mirror is not moving or is slowing-down, then an alarm sequence is generated and the spinning motor is cut-off, the brake disc 10 is advanced and the tracking motors are actuated misaligning the collector from the sun by going to a reset position.

Turning-off sequence begins with the misaligning from the sun and going to the reset position, cutting-off the spinning mirror motor and advancing the disc brake 10.

The elements of FIG. 7 inside the dash line are powered by a super-capacitor charged during normal operation by the PV generator. This is increasing the flexibility of system design because a battery is no longer mandatory. At the same time, the life of the system is improved because a super-capacitor has a much longer life than a battery and is able to be fully discharged until start-up or safety sequence is accomplished.

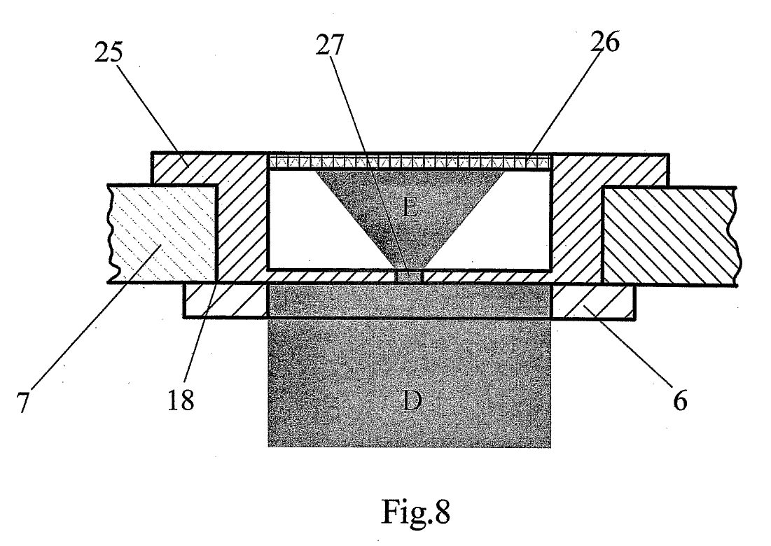

FIG. 8 shows the structure of the safety window 18. A safety optical sensor 26 is embedded in a ceramic cover 25 which reacts to a very small portion of the intense beam D passing through a tiny hole 27 and diffused in a large cone E. This structure protects the safety sensor itself against overheating or burning if the beam D is resting too long on the window 18. The cover 25 is sealed to maintain the vacuum in the enclosure 7.

The safety sensor 26 sends to the microprocessor a continuous signal if the spinning mirror is not moving or a pulsed signal after starting it. The frequency of the pulsed signal provides information on the mirror speed which is used for controlling it. This frequency will be also the frequency of the output current of the PV generator if the AC option is taken into consideration. The microprocessor can be used as a PLL (Phase Locked Loop) for controlling the frequency and phase of the AC output by suitable programming.

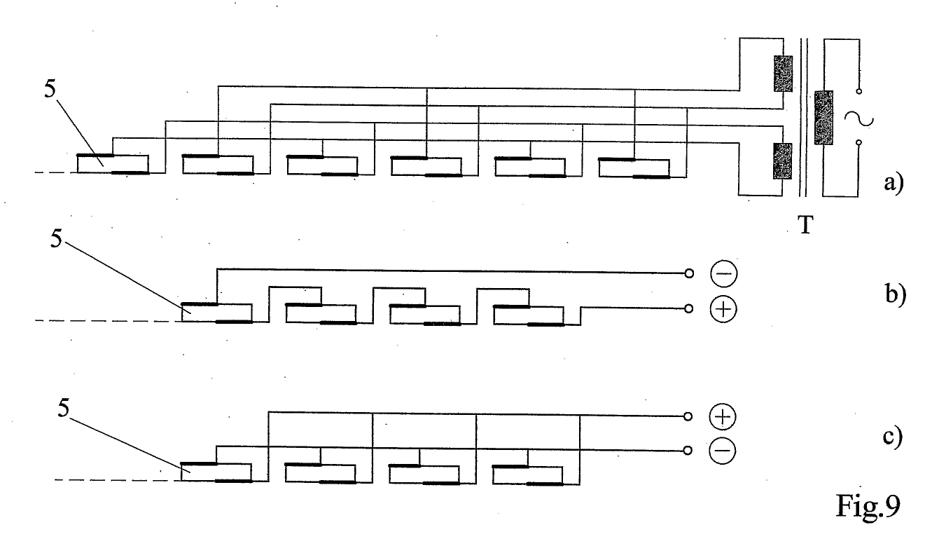

FIGS. 9A, 9B and 9C show three alternative connection patterns of the PV cells. For single-phase AC generation shown in FIG. 9A, a transformer T is necessary for bringing the output voltage to the desired value and for insuring a true-sinusoidal waveform. Its two primary identical windings are connected to the odd and even numbered PV cells in parallel, respectively. The speed of the spinning mirror and the magnetic material of the transformer's core are adjusted to the desired frequency of the output AC which is not limited to 50 or 60 Hz.

For DC generation shown in FIGS. 9B and 9C, series and parallel connection of the PV cells are possible, according to the desired output voltage and current. The PV cells mounted on the support 6 can be connected all in one circuit or they can be grouped in phased clusters and connected in multiple circuits. It is understood that for the ease of illustration, the PV cells 5 are shown in a straight line representing the unwrapped circular profile of the support 6.

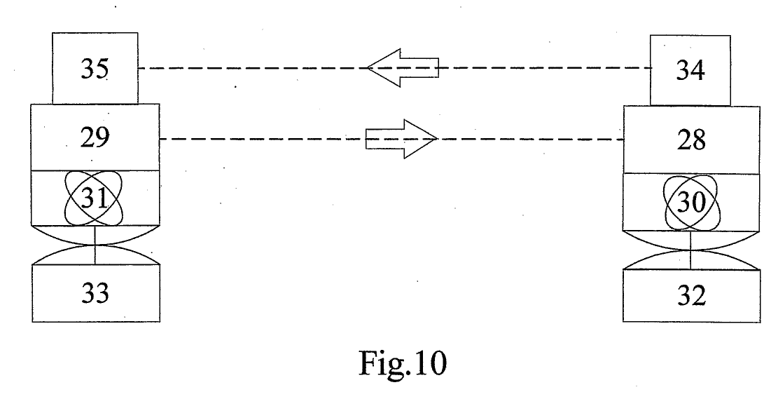

Another arrangement shown herein in FIG. 10 is the PV conversion of artificial light, addressed to a special class of applications, where the system shown uses a modular PV generator 28 which may be of the type described above in relation to the apparatus of FIG. 1 or FIG. 4 or FIG. 6 in conjunction with an IR laser 29.

Remote transmissions of data or power through laser beams from high buildings or towers may be affected by small vibrations to which the transmitter or the receiver could be subject of due to wind, nearby traffic, etc. Thus, each of them is preferably supported by a gyroscopic platform 30 and 31 respectively and optionally by a dual-axis aligning platform 32 and 33. The laser assembly is the master unit and the PV generator assembly is the slave unit. The master unit delivers the energy and initiates all the protocols for a proper functioning of the slave unit. Depending of the tasks the slave unit has to accomplish, it is equipped with a radio or laser data transmitter 34 and the master unit with the appropriate receiver 35. It is understood that the PV cells inside the module 28 are arranged to match the wavelength of the laser for achieving the best efficiency.

The slave unit can be a small robot, a radio-relay or a remote sensing device which has no other power source or uses this PV generator just as a backup. If the remote slave unit is rarely interrogated by a master data acquisition system, then for powering it a battery is not the best choice.

In some military and space applications, the slave unit could even be on the move and the optical alignment with the master unit to be maintained in a certain range of speed and change of direction.

Another embodiment associates PV generation as shown above with hybrid or remote lighting.

In hybrid lighting, a collector concentrates sunlight and filters the visible part of it using cold mirrors or other optical arrangements. Sunlight is then efficiently piped into buildings and routed into several light fixtures that combine natural and artificial light to insure a constant light output whatever the weather conditions are. This is accomplished by electronically sensing sunlight intensity and dimming the fluorescent bulbs accordingly. The main drawback of this technology is the limited number of optical fibers that can populate the focus of the collector, i.e. the limited number of light fixtures fed by a collector. For increasing the number of light fixtures, the only possibility is to use several collectors which make the technology unaffordable for most users.

The solution brought by the present arrangement is to multiply by hundreds the number of lighting fixtures using light originated from a single collector. Sunlight concentrated by the collector is first directed to an optical distributor essentially comprising the spinning mirror 3 driven by the electric motor 4 in which all or part of the PV cells 5 are replaced with heads of optical fibers that are feeding lighting fixtures. Each lighting fixture will illuminate the designated area not with a continuous flux of light but with a flickering one. If the frequency of turning light on and off is over 50 Hz, then, to the human eye, it will appear a continuous one, exactly like that emitted by a fluorescent bulb. However, the duty cycle of turning on and off the light transported by each optical fiber is not 50%. During one revolution, each fiber is “seeing” a short light pulse. Consequently, the perception of light will be more intense if the frequency of the pulses will be higher, this way avoiding flickering too. While each lighting fixture may be fed with light from a single fiber at a single location on the reception cylinder, in order to increase the amount of light and reduce the frequency, two or more optical fibers can be used at equal angular spacing in respect to the axis of the spinning mirror, their pulsing thus being out of phase.

Remote lighting can benefit from the same concept and considerations if the illuminators or light engines are redesigned. Light originating in most cases from a HID lamp is focused on a bundle of optical fibers that distribute it to a number of lighting fixtures. If light emitted by the same source is firstly collimated and directed to a spinning mirror 3 driven by an electric motor 4, then it can be distributed to a much larger number of optical fibers feeding lighting fixtures.

Since various modifications can be made in my invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. Apparatus comprising:
a collector for light from a source;
a plurality of light receivers each for receiving light from the collector;
the light receivers being arranged in an array surrounding an axis;
the collector being arranged to direct the light in a beam along the axis;
a light redirecting member arranged on the axis and arranged to redirect the light in the beam away from the axis such that the redirected beam lies in a plane radial to the axis;
and a drive arrangement for rotating the light redirecting member around the axis such that the redirected beam rotates around the axis and falls sequentially and repeatedly on each of the receivers as the member rotates.

2. The apparatus according to claim 1 wherein the receivers are arranged for converting light into electricity and each comprises a respective one of a plurality of PV cells.

3. The apparatus according to claim 1 or 2 wherein the collector is arranged for collecting sunlight.

4. The apparatus according to claim 1 or 2 wherein the collector is arranged for collecting light from an electric light source.

5. The apparatus according to any preceding claim wherein the light redirecting member comprises a mirror.

6. The apparatus according to any preceding claim wherein the light redirecting member is driven by an electric motor.

7. The apparatus according to any preceding claim wherein the collector includes a collimator for guiding the beam parallel to the axis.

8. The apparatus according to any preceding claim wherein the light redirecting member is arranged to direct the light into a radial plane of the axis.

9. The apparatus according to any preceding claim wherein the receivers are arranged on an inside of a surface surrounding the axis.

10. The apparatus according to any preceding claim wherein there is provided a magnetic brake for always stopping the light redirecting member in the same rest angular position.

11. The apparatus according to claim 10 wherein there is provided a drive member for driving the magnetic brake axially for engaging a cooperating element on the light redirecting member.

12. The apparatus according to claim 10 or 11 wherein there is provided a safety window corresponding to the rest angular position of the light redirecting member.

13. The apparatus according to any preceding claim wherein there is provided a vacuum enclosure housing surrounding the light redirecting member and the receivers.

14. The apparatus according to any preceding claim wherein there is provided a dual-axis tracking platform supporting the collector.

15. The apparatus according to any preceding claim wherein there is provided a plurality of collectors arranged in an array.

16. The apparatus according to claim 15 wherein the collectors are hexagonal and mounted in a honeycomb pattern.

17. The apparatus according to claim 15 or 16 wherein the collectors are mounted in the same plane and there is provided for each collector an array of light receivers where the arrays are arranged in different planes in such a way that incident and reflected collimated beams are intersecting at right angles but are not shading or interfering to each other.

18. The apparatus according to any preceding claim wherein the collector is protected by a transparent, anti-reflecting dome against extreme weather conditions.

19. The apparatus according to any preceding claim wherein the collector includes an optical cable such that the concentrated light is transported through the optical cable to the light redirecting member.

20. The apparatus according to any preceding claim wherein the light redirecting member light receivers are PV cells which are connected in series or in parallel for delivering DC.

21. The apparatus according to any preceding claim wherein the light redirecting member light receivers are PV cells which are connected in phased clusters connected to a transformer for delivering a true-sine single or three-phase AC.

22. The apparatus according to claim 21 wherein voltage, phase and frequency are controlled by controlling the rate of the rotation of the light redirecting member.

23. The apparatus according to any preceding claim wherein the source comprises a laser transmitted from a central station and the collector is mounted at a slave station.

24. The apparatus according to any preceding claim wherein each of the receivers comprises a respective one of a plurality of light transfer pipes such that concentrated and filtered sunlight can be piped from a roof sun-tracking collector through an optical cable and can be distributed by the light transfer pipes to a respective one of a plurality of lighting fixtures in a building.
